(19) United States
(12) Patent Application Publication
(10) Pub. No.: US 2008/0131735 A1
(43) Pub. Date: Jun. 5, 2008

(54) Ni-X, Ni-Y, and Ni-X-Y alloys with or without oxides as sputter targets for perpendicular magnetic recording

(75) Inventors: Anirban Das, Chandler, AZ (US); Steven Roger Kennedy, Chandler, AZ (US); Michael Gene Racine, Phoenix, AZ (US)

Correspondence Address: MCDERMOTT WILL & EMERY LLP, 18191 VON KARMAN AVE., SUITE 500, IRVINE, CA, 92612-7108, US

(73) Assignee: Heraeus Incorporated, Chandler, AZ (US)

(21) Appl. No.: 11/633,576

(22) Filed: Dec. 5, 2006

(51) Int. Cl. G11B 5/66; C23C 14/34

(52) U.S. Cl. 428/831; 106/1.14; 106/1.13; 106/1.15; 106/1.12; 106/1.16; 106/1.18; 106/1.19; 106/1.21; 106/1.05; 204/192.15

(57) ABSTRACT

The various embodiments of the present invention generally relate to the deposition of a seedlayer for a magnetic recording medium used for perpendicular magnetic recording (PMR) applications, where the seedlayer provides for grain size refinement and reduced lattice mis-fit for a subsequently deposited underlayer or granular magnetic layer, and where the seedlayer is deposited using a nickel (Ni) alloy based sputter target. The nickel (Ni) alloy can be binary (Ni—X; Ni—Y) or ternary (Ni—X—Y). In addition, the binary (Ni—X; Ni—Y) or ternary (Ni—X—Y) nickel (Ni) based alloys can be further alloyed with metal oxides, thus forming seedlayer thin films with a granular microstructure containing metallic grains, surrounded by an oxygen rich grain boundary. The nickel-based alloys (with or without metal oxides) of the various exemplary embodiments can be made by powder metallurgical technique or by melt-casting techniques, with or without thermo-mechanical working.

### STATEMENT REGARDING FEDERALLY SPONSORED RESEARCH OR DEVELOPMENT

Not Applicable.

### BACKGROUND

1. Field

The present invention generally relates to sputter targets and, more particularly, relates to the deposition of a seedlayer for a magnetic recording medium used for perpendicular magnetic recording (“PMR”) applications, where the seedlayer provides for grain size refinement and reduced lattice mis-fit for a subsequently deposited underlayer or granular magnetic layer, and where the seedlayer is deposited using nickle (Ni) alloy based sputter target.

2. Background

The process of direct current (“DC”) magnetron sputtering is widely used in a variety of fields to provide thin film material deposition of a precisely controlled thickness and within narrow atomic fraction tolerances on a substrate, for example to coat semiconductors or to form films on surfaces of magnetic recording media. In one common configuration, a racetrack-shaped magnetic field is applied to the sputter target by placing magnets on the backside surface of the target. Electrons are trapped near the sputtering target, improving argon ion production and increasing the sputtering rate. Ions within this plasma collide with a surface of the sputter target causing the sputter target to emit atoms from the sputter target surface. The voltage difference between the cathodic sputter target and an anodic substrate that is to be coated causes the emitted atoms to form the desired film on the surface of the substrate.

Other common approaches to sputtering include conventional co-sputtering, and co-sputtering using a triatron. In the co-sputtering process, multiple independent sputter targets with independent power supplies are positioned within the vacuum chamber and sputtered simultaneously, where the uniformity of the deposited surface is controlled by selectively sputtering one or more of the multiple sputter targets. To sputter a X1-X2 thin film using conventional co-sputtering, for example, a sputter target comprised of X1 would be placed in the vacuum chamber with a sputter target comprised of X2, and sputtering would occur on both sputter targets simultaneously. Triatron configuration co-sputtering, on the other hand, uses a single sputter target with multiple independent regions of composition. Adapting the above example to a triatron configuration, a single triatron sputter target would have an region comprised solely of X1 and a region comprised solely of X2, where both regions would be co-sputtered simultaneously to deposit an X1-X2 thin film.

During the production of conventional magnetic recording media, layers of thin films are sequentially sputtered onto a substrate by multiple sputter targets, where each sputter target is comprised of a different material, resulting in the deposition of a thin film “stack.” FIG. 1 illustrates typical thin film stack 100 for conventional magnetic recording media. At the base of stack 100 is non-magnetic substrate 102, which is typically aluminum or glass. Seed layer 104 is deposited over substrate 102, where seedlayer 104 forces the shape and orientation of the grain structure of higher layers, and is commonly comprised of tantalum (Ta).

Next, underlayer 106, which often includes one to three discrete layers, is deposited over seedlayer 104, where underlayer 106 is typically very weakly-magnetic, crystalline, and hexagonal close-packed (“HCP”). Underlayer 106 is used to enhance the Co (0002) texture of the subsequently-deposited, cobalt (Co)-based magnetic data-storing granular layer 108 perpendicular to the film plane, leading to a increased perpendicular anisotropy of the media. Magnetic data-storing granular layer 108 is subsequently deposited over underlayer 106, and optional additional layers 110, such as a lubricant layer or carbon (C) overcoat, are deposited over granular layer 108.

Underlayer 106 enhances the crystallographic texturing of the subsequently deposited magnetic data-storing granular layer 108. Furthermore, if magnetic data-storing granular layer 106 is grown epitaxially on top of a refined grain sized, crystalline underlayer, the grain size of magnetic data-storing granular layer 108 is refined as well. Additionally, close lattice matching between underlayer 106 and magnetic data-storing granular layer 108 provides a substantially defect-free interface, potentially reducing contribution to any in-plane magnetization.

The amount of data that can be stored per unit area on a magnetic recording medium is directly related to the metallurgical characteristics and the composition of the magnetic data-storing granular layer and, correspondingly, to the sputter target material from which the magnetic data-storing granular layer is sputtered. In recent years, the magnetic data storage industry has pursued a technology known as ‘PMR’ (as opposed to conventional ‘longitudinal magnetic recording’ (“LMR”)) to sustain the demand for continuous growth in data storage capacity. PMR has a higher write efficiency using a perpendicular single-pole recording head in combination with a soft underlayer, where bits are recorded perpendicular to the plane of the magnetic recording medium, allowing for a smaller bit size and greater coercivity. In the future, PMR is expected to increase disk coercivity and strengthen disk signal amplitude, translating into superior archival data retention.

In order to achieve a high recording density in PMR media, thermal stability should be high, and media noise performance should be low. One approach to realizing the essential thermal stability and media noise requirements in PMR media is to provide a granular magnetic media with magnetic domains having high magnetocrystalline anisotropy (Kᵤ), and to adequately encapsulate a fine grain microstructure in a structurally, magnetically and electrically insulating matrix. Although significant anisotropic energy is already required by conventional LMR, PMR requires a much finer grain microstructure with adequate grain-to grain segregation and negligible cross-talk between the magnetic domains, in order to achieve low media noise performance and high thermal stability.

The inclusion of an oxygen-rich grain boundary region has significantly improved grain refinement and has provided excellent microstructural, magnetic and electrical isolation. In this regard, oxygen (O)-containing magnetic data storing layer 106 often includes at least one CoCrPt-based alloy layer, since oxygen (O) in the grain boundary region forms an amorphous, hard and brittle grain boundary region which confines the grain growth and helps refine the grain size of these oxide-containing granular layers. Other high or low moment CoPt(Cr)(B)-based magnetic data storing layers are also commonly subsequently deposited on this CoCrPt-based granular magnetic layer in order to adjust the saturation magnetization (Ms) commensurate with specified disk head design.

It is therefore considered highly desirable to improve upon known sputter target alloys and compositions to provide for the deposition of a magnetic data-storing granular layer with greater data-storage potential, with particular regard to magnetic data-storing granular layers used in PMR. Specifically, it is highly desirable to provide a sputter target which, when sputtered as a seedlayer, provides increased crystallinity and further grain size refinement to a subsequently deposited underlayer or magnetic data-storing granular layer.

### SUMMARY

The present invention addresses the above-described deficiencies of typical sputter target alloys and compositions. The various embodiments of the present invention generally relate to the deposition of a seedlayer for a magnetic recording medium used for PMR applications, where the seedlayer provides for grain size refinement and reduced lattice mis-fit for a subsequently deposited underlayer or granular magnetic layer, and where the seedlayer is deposited using a nickel (Ni) alloy based sputter target. The present invention also relates to binary and ternary nickel (Ni) alloys as sputter target material which can be reactively sputtered to form magnetic data-storing granular layers having granular media with optimized grain size and improved grain-to-grain separation.

According to at least one exemplary embodiment of the present invention, a magnetic recording medium has a substrate, with a seedlayer deposited over the substrate. The seedlayer is comprised of nickel (Ni), an alloying element (X), and metal oxide. An underlayer is deposited over the seedlayer, and a magnetic data-storing granular layer deposited over the underlayer. The solubility of the alloying element in a face-centered cubic nickel (Ni) phase does not exceed 50 atomic percent at room temperature or at elevated temperatures. In addition, the alloying element (X) has a mass susceptibility of less than or equal to

$$1.5 \times {10}^{- 7} \frac{{m}^{3}}{kg} .$$

The alloying element is selected from boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th).

The alloying element (X) in the crystalline nickel (Ni) alloy based seedlayer promotes refined grain size. Just as the refined grain size of the crystalline underlayer helps reduce the grain size reduction of the subsequently deposited granular magnetic layer, a similar effect is realized by the underlayer if the underlayer is subsequently deposited epitaxially on top of the reduced grain size, crystalline nickel alloy (Ni—X) based seedlayer. Various exemplary embodiments of the present invention provide for a promotion of grain size refinement by alloying nickel (Ni) with an element (X) which acts as a grain size refiner in the crystalline nickel (Ni) alloy based seedlayer film, so the alloying element has little or no solubility in face-centered cubic nickel (Ni) phase at room temperature, such that the alloying element forms the amorphous grain boundary region in the nickel (Ni) alloy based seedlayer film and helps in grain size reduction by confining any further grain growth during processing.

In at least one exemplary embodiment of the invention, a sputter target has nickel (Ni), and an alloying element (X) selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th), with the alloying element present in the sputter target in an amount exceeding a solid solubility limit of the alloying element in face-centered cubic (FCC) phase nickel (Ni) at or above room temperature. The sputter target also has metal oxide.

According to at least one exemplary embodiment of the present invention, a magnetic recording medium has a substrate, and a seedlayer deposited over the substrate. The seedlayer comprised of nickel (Ni), an alloying element (Y), and metal oxide. An underlayer deposited over the seedlayer, and a magnetic data-storing granular layer deposited over the underlayer. Preferably, the alloying element (Y) is added to nickel (Ni) at less than or equal to 10 atomic percent of its maximum solubility limit at or above room temperature. The alloying element (Y) is soluble in nickel (Ni) at room temperature or at elevated temperatures. Also, the alloying element has a mass susceptibility of less than or equal to

$$1.5 \times {10}^{- 7} \frac{{m}^{3}}{kg} .$$

### In addition, the alloying element has an atomic radius greater than 1.24 Å.

The alloying element (Y) is selected from aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

Due to the symmetry of the (111) plane of the face-centered cubic (FCC) nickel (Ni), the present invention provides for the reduction of lattice mis-fit of crystalline underlayers, such as ruthenium (Ru) or ruthenium (Ru)-based underlayers or underlayers composed of different base metals, and nickel alloy (Ni—Y) based seedlayers by alloying the crystalline seedlayer of nickel (Ni) with elements (Y) which are soluble in at room temperature or at higher temperatures. The (0002) orientation in the ruthenium (Ru) or ruthenium (Ru)-based alloys underlayer also promotes strong (0002) texture growth in the granular magnetic recording layer. These alloying elements can form solid solutions with nickel (Ni) at room temperature or at elevated temperatures, and thus accordingly modify the in-plane lattice parameter of nickel (Ni), thereby reducing the lattice mis-fit.

In at least one embodiment of the present invention, a sputter target has nickel (Ni), an alloying element (Y) selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb), where the alloying element present in the sputter target in an amount exceeding a solid solubility limit of the alloying element in face-centered cubic (FCC) phase nickel (Ni) at or above room temperature. The sputter target also has metal oxide.

According to at least one embodiment of the present invention, a magnetic recording medium has a substrate, with a seedlayer deposited over the substrate. The seedlayer is comprised of nickel (Ni), a first alloying element (X), and a second alloying element (Y). An underlayer is deposited over the seedlayer, with a magnetic data-storing granular layer deposited over the underlayer. The solubility of the first alloying element (X) in a face-centered cubic nickel (Ni) phase does not exceed 50 atomic percent at room temperature or at elevated temperatures. The second alloying element (Y) is added to nickel (Ni) at less than or equal to 10 atomic percent of its maximum solubility limit at or above room temperature, and has an atomic radius greater than 1.24 Å. Moreover, the first alloying element and the second alloying element have a mass susceptibility of less than or equal to

$$1.5 \times {10}^{- 7} \frac{{m}^{3}}{kg} .$$

Accordingly, a ternary nickel alloy (Ni—X—Y) can be formed comprising both grain size reforming elements (X) and soluble elements (Y) for reducing lattice mismatch and eliminating interface stresses. In various exemplary embodiments, the seedlayer is further comprised of metal oxide.

The first alloying element is selected from boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th). The second alloying element is selected from aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

In at least one embodiment of the present invention, a sputter target has a sputter target has nickel (Ni), and a first alloying element selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th), with the first alloying element present in the sputter target in an amount exceeding a solid solubility limit of the alloying element in face-centered cubic (FCC) phase nickel (Ni) at or above room temperature. The sputter target can further include a second alloying element, where the second alloying element the second alloying element having a solid solubility limit in face-centered cubic (FCC) phase nickel (Ni) of less than or equal to 10 atomic percent at or above room temperature, the second alloying element having a mass susceptibility of less than or equal to

$$1.5 \times {10}^{- 7} \frac{{m}^{3}}{kg} ,$$

with the second alloying element present in the sputter target in an amount not exceeding the solid solubility limit of the second alloying element. The second alloying element is selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb), where the second alloying element present in the sputter target in an amount exceeding a solid solubility limit of the alloying element in face-centered cubic (FCC) phase nickel (Ni) at or above room temperature. In various exemplary embodiments of the invention, the sputter target is further comprised of metal oxide.

At least one exemplary embodiment of the present invention relates to a method of manufacturing a magnetic recording medium. At least a first seedlayer is sputtered over a substrate from a first sputter target, where the first sputter target is comprised of nickel (Ni) and an alloying element (X), wherein solubility of the alloying element in a face-centered cubic nickel (Ni) phase does not exceed 50 atomic percent at or above room temperature, and where the alloying element has a mass susceptibility of less than or equal to

$$1.5 \times {10}^{- 7} \frac{{m}^{3}}{kg} .$$

The first sputter target is further comprised of metal oxide. At least a first underlayer is sputtered over the first seedlayer from a second sputter target. In addition, at least a first magnetic data-storing granular layer is sputtered over the first underlayer from a third sputter target.

At least one exemplary embodiment of the present invention relates to a method of manufacturing a magnetic recording medium. At least a first seedlayer is sputtered over a substrate from a first sputter target, where the first sputter target is comprised of nickel (Ni) and an alloying element (Y), where solubility of the alloying element in a face-centered cubic nickel (Ni) phase is less than or equal to 10 atomic percent at or above room temperature, and where the alloying element has a mass susceptibility of less than or equal to

$$1.5 \times {10}^{- 7} \frac{{m}^{3}}{kg} .$$

The sputter target is further comprised of metal oxide. At least a first underlayer is sputtered over the first seedlayer from a second sputter target. In addition, at least a first magnetic data-storing granular layer is sputtered over the first underlayer from a third sputter target.

At least one exemplary embodiment of the present invention relates to a method of manufacturing a magnetic recording medium. At least a first seedlayer is sputtered over a substrate from a first sputter target, wherein the first sputter target is comprised of nickel (Ni) and a first alloying element and a second alloying element, where the solubility of the first alloying element in a face-centered cubic nickel (Ni) phase does not exceed 50 atomic percent at room temperature, where the solubility of the second alloying element in a face-centered cubic nickel (Ni) phase is less than or equal to 10 atomic percent of its maximum solubility limit at or above room temperature, and where the first and second alloying elements have a mass susceptibility of less than or equal to

$$1.5 \times {10}^{- 7} \frac{{m}^{3}}{kg} .$$

At least a first underlayer is sputtered over the first seedlayer from a second sputter target. Also, at least a first magnetic data-storing granular layer is sputtered over the first underlayer from a third sputter target. In various exemplary embodiments, the first sputter target may be further comprised on metal oxide.

The seedlayer or sputter targets of various exemplary embodiments may have metal oxide. The metal oxide can have at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide can have a reduction potential more negative than nickel (Ni). An advantage of alloying the binary (Ni—X; Ni—Y) or ternary (Ni—X—Y) nickel based alloys with metal oxides is that the resulting deposited film or sputter target has a granular alloy microstructure with oxygen rich grain boundaries to provide further grain size refinement.

Advantages of the various exemplary embodiments described above include, but are not limited to, providing for grain size refinement and reduced lattice mis-fit for a subsequently deposited underlayer or granular magnetic layer, as well as improving the Signal-to-Noise Ratio (SNR) and increasing the magnetocrystalline anisotropy Kᵤ in the media stack for PMR. The various embodiments described above also advantageously improve sputter targets.

It is understood that other embodiments of the present invention will become readily apparent to those skilled in the art from the following detailed description, wherein it is shown and described only various embodiments of the invention by way of illustration. As will be realized, the invention is capable of other and different embodiments and its several details are capable of modification in various other respects, all without departing from the spirit and scope of the present invention. Accordingly, the drawings and detailed description are to be regarded as illustrative in nature and not as restrictive.

### BRIEF DESCRIPTION OF THE DRAWINGS

Referring now to the drawings in which like reference numbers represent corresponding parts throughout:

FIG. 1 illustrates a typical prior art thin film stack for conventional PMR media;

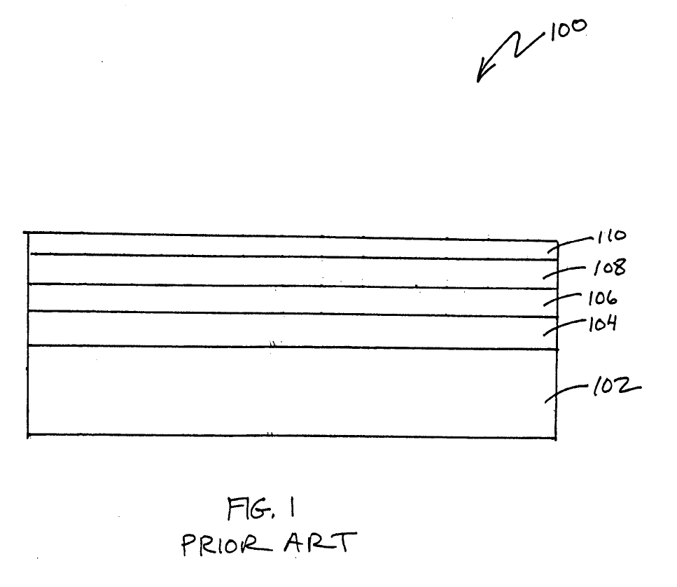

FIG. 2 illustrates a thin film stack for PMR media according to various exemplary embodiments of the present invention;

FIG. 3 illustrates a sputter target according to various embodiments of the present invention;

FIG. 4 illustrates an exemplary lattice misfit diagram of an face-centered Cubic (111) Ni plane and a Ru (0002) plane; and

FIG. 5 illustrates a flowchart depicting a method for manufacturing a magnetic recording medium according to various exemplary embodiments of the present invention.

### DETAILED DESCRIPTION

The various embodiments of the present invention generally relate to the deposition of a seedlayer for a magnetic recording medium used for perpendicular magnetic recording (PMR) applications, where the seedlayer provides for grain size refinement and reduced lattice mis-fit for a subsequently deposited underlayer or granular magnetic layer, and where the seedlayer is deposited using a nickel (Ni) alloy based sputter target. The nickel (Ni) alloy can be binary (Ni—X; Ni—Y) or ternary (Ni—X—Y). In addition, the binary (Ni—X; Ni—Y) alloys are further alloyed with metal oxide. The ternary (Ni—X—Y) nickel (Ni) based alloys may, in various embodiments, be further alloyed with metal oxides. The nickel (Ni) alloys with metal oxide form seedlayer thin films with a granular microstructure containing metallic grains, surrounded by an oxygen rich grain boundary. The nickel-based alloys (with or without metal oxides) of the various exemplary embodiments can be made by powder metallurgical technique or by melt-casting techniques, with or without thermo-mechanical working.

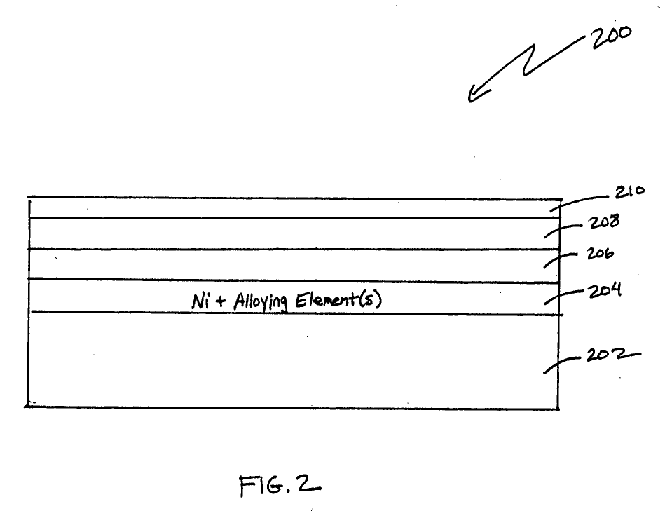

FIG. 2 illustrates an exemplary thin film stack in accordance with various embodiments of the present invention. Magnetic recording medium 200 includes substrate 202 and seedlayer 204 deposited over substrate 202, seedlayer 204 comprised of nickel (Ni) and an alloying element. While omitted from the illustration in FIG. 2, in various exemplary embodiments, at least one layer may be deposited between substrate 202 and seedlayer 204. The at least one layer may be an underlayer, anti-ferromagnetic layer, or other type of layer that may comprise either magnetic or non-magnetic materials.

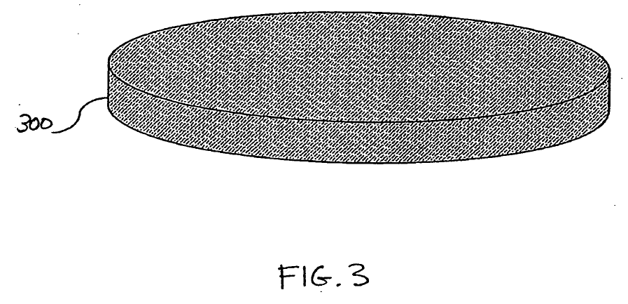

In various embodiments of the invention, seedlayer 204 is comprised of nickel (Ni), a first alloying element, and a second alloying element. The nickel (Ni) based alloy of seedlayer 204 can be further alloyed with metal oxides, thus forming seedlayer thin films with a granular microstructure containing metallic grains, surrounded by an oxygen rich grain boundary. The metal oxide can have at least one metal element that is silicon (Si), aluminum (Al), titanium (Ti), niobium (Nb), tantalum (Ta), zirconium (Zr), hafnium (Hf), tungsten (W), or any lanthanide, or any combination thereof. Moreover, seedlayer 204 can be sputter deposited from a sputter target such as a sputter target 300 in FIG. 3 according to various embodiments of the present invention.

The magnetic recording medium also includes underlayer 206 deposited over seedlayer 204, and magnetic data-storing granular layer 208 deposited over underlayer 206. Close lattice matching between underlayer 206 and magnetic data-storing granular layer 208 ensures almost a defect free interface and thus can potentially reduce contribution to any in-plane magnetization. Underlayer 206 is comprised of ruthenium (Ru) or a ruthenium (Ru)-based alloy, although other base metals typically used in the art may be used in conjunction with or instead of ruthenium (Ru). In various embodiments, underlayer 206 may have a crystalline structure. For example, underlayer 206 may have a hexagonal close-pack structure. Additionally, in various exemplary embodiments of the invention, underlayer 206 is weakly magnetic or non-magnetic in nature. Underlayer 206 not only enhances the crystallographic texturing of magnetic data-storing granular layer 208, but also can help in the grain size refinement of magnetic data-storing granular layer 208, if magnetic data-storing granular layer 208 is grown epitaxially on top of underlayer 206 with refined grain size.

Magnetic data-storing granular layer 208 is deposited over underlayer 206. Magnetic data-storing granular layer 208 can be CoCrPt, and, in various exemplary embodiments, can further comprise oxygen (O). Additionally, a lubricant layer or carbon overcoat layer may be deposited above magnetic data-storing granular layer 208 (or saturation magnetization layer 210, if it is included). The lubricant layer or carbon overcoat layer may serve as a protectant. Furthermore, additional magnetic or non-magnetic layers may be deposited above magnetic data-storing granular layer 208.

The exemplary magnetic recording medium 200 of FIG. 2 additionally illustrates saturation magnetization adjustment layer 210. Saturation magnetization adjustment layer 210 can be CoPt, or CoPt can be further alloyed with chromium (Cr) or boron (B), or any combination thereof. In various embodiments of the present invention, saturation magnetization adjustment layer 210 can be omitted.

### Ni—X

According to at least one exemplary embodiment of the present invention, a binary (Ni—X) alloy can be utilized to promote grain size refinement in the crystalline underlayer in a magnetic recording medium. The magnetic recording medium has a substrate, with a seedlayer deposited over the substrate. The seedlayer is comprised of nickel (Ni), an alloying element (X), and a metal oxide. An underlayer is deposited over the seedlayer, and a magnetic data-storing granular layer deposited over the underlayer. The solubility of the alloying element in a face-centered cubic nickel (Ni) phase does not exceed 50 atomic percent at room temperature or at elevated temperatures. In addition, the alloying element has a mass susceptibility of less than or equal to

$$1.5 \times {10}^{- 7} \frac{{m}^{3}}{kg} .$$

The alloying element (X) is selected from boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th). The metal oxide can have at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide can have a reduction potential more negative than nickel (Ni). An advantage of the nickel (Ni) alloy (Ni—X) with metal oxide is that the resulting deposited film or sputter target has a granular alloy microstructure with oxygen rich grain boundaries to provide further grain size refinement.

The alloying element (X) in the crystalline nickel (Ni) alloy based seedlayer promotes refined grain size. Just as the refined grain size of the crystalline underlayer helps reduce the grain size reduction of the subsequently deposited granular magnetic layer, a similar effect is realized by the underlayer if the underlayer is subsequently deposited epitaxially on top of the reduced grain size, binary crystalline nickel alloy (Ni—X) based seedlayer with metal oxide. Various exemplary embodiments of the present invention provide for a promotion of grain size refinement by alloying nickel (Ni) with an element (X) which acts as a grain size refiner in the crystalline nickel (Ni) alloy based seedlayer film, so the alloying element has little or no solubility in face-centered cubic nickel (Ni) phase at room temperature, such that the alloying element forms the amorphous grain boundary region in the nickel (Ni) alloy based seedlayer film and helps in grain size reduction by confining any further grain growth during processing.

The alloying element (X) is non-magnetic or weakly magnetic in nature, with a mass susceptibility of less than or equal to

$$1.5 \times {10}^{- 7} \frac{{m}^{3}}{kg} .$$

Table 1, below, provides a list of alloying elements (X) which can be alloyed with nickel (Ni) to form an enhanced alloy (Ni—X) which provides for grain size reduction in the seedlayer film, although other elements which meet these characteristics-may also be used as well.

TABLE 1
Alloying Elements Which Provide For Grain Size Refinement

| | | | | | Room |
|---|---|---|---|---|---|
| | | | | Mass | Temperature |
| | Atomic | Atomic | | Susceptibility | (RT) Solubility in |
| Element | Number | Radius | Structure | (10⁻⁸ m³/kg) | Nickel (Ni) |
| B | 5 | 0.97 Å | Rhombohedral | −0.87 | Insoluble |
| C | 6 | 0.77 Å | Diamond | −0.62 | 1326 C. |
| | | | Cubic | | (2.7%); |
| | | | | | Insoluble |
| | | | | | (RT) |
| Mn | 25 | 1.35 Å | Cubic | 12.2 | Insoluble |
| Cu | 29 | 1.28 Å | Face-Centered Cubic | −0.1 | Insoluble |
| Y | 39 | 1.81 Å | Hexagonal | 6.66 | Insoluble |
| | | | Close-Pack | | |
| Zr | 40 | 1.60 Å | Hexagonal | 1.66 | 1170 C. |
| | | | Close-Pack | | (1.78%); |
| | | | | | Insoluble |
| | | | | | (RT) |
| Rh | 45 | 1.34 Å | Face-Centered Cubic | 1.32 | Insoluble |
| Ag | 47 | 1.44 Å | Face-Centered | −0.23 | 1435 C. (3%); |
| | | | Cubic | | Insoluble |
| | | | | | (RT) |
| Cd | 48 | 1.52 Å | Hexagonal | −0.23 | Insoluble |
| | | | Close-Pack | | |
| Yb | 70 | 1.93 Å | Face-Centered | 0.59 | Insoluble |
| | | | Cubic | | |
| Hf | 72 | 1.59 Å | Hexagonal | 0.53 | 1190 C. (1%); |
| | | | Close-Pack | | Insoluble |
| | | | | | (RT) |
| Ir | 77 | 1.35 Å | Face-Centered | 0.23 | Insoluble |
| | | | Cubic | | |
| Pt | 78 | 1.38 Å | Face-Centered | 1.22 | Insoluble |
| | | | Cubic | | |
| Au | 79 | 1.44 Å | Face-Centered | −0.18 | Insoluble |
| | | | Cubic | | |
| Bi | 83 | 1.75 Å | Monoclinic | −1.70 | Insoluble |
| Th | 90 | 1.80 Å | Face-Centered | 0.53 | Insoluble |
| | | | Cubic | | |

The alloying element (X) can be added anything in excess of its maximum solubility limit (room temperature or higher) and added to be greater than or equal to 50 atomic percent. The alloying element (X) can be added in high atomic percentages, such as 50% in the nickel (Ni) based alloy, although higher or lower atomic percentages can also be used as desired. The alloying element can also be added in excess of its maximum solubility limit, at room temperature or higher temperatures. “Higher” than room temperature or “elevated” over room temperature means any temperature over room temperature, which is ordinarily considered approximately 20-23° C., or 68-73° F. Example temperatures which would be higher than or elevated over room temperature would be 25° C., 100° C., 1000° C., 2500° C., or 5000° C.

Nickel (Ni), the alloying element (X), and metal oxide can used in a sputter target such as sputter target 300 of FIG. 3. The alloying element (X) present in the sputter target is in an amount exceeding a solid solubility limit of the alloying element in face-centered cubic (FCC) phase nickel (Ni) at or above room temperature. In addition, the alloying element (X) can be present in the sputter target in an amount no more than 50 atomic percent greater than the solid solubility limit of the alloying element in face-centered cubic (FCC) phase nickel (Ni) at or above room temperature. Moreover, the alloying element (X) has a mass susceptibility of less than or equal to

$$1.5 \times {10}^{- 7} \frac{{m}^{3}}{kg} .$$

### Ni—Y

According to at least one exemplary embodiment of the present invention, an alloying element (Y) of a binary seedlayer alloy (Ni—Y) further having metal oxide can reduce lattice mis-fit for a magnetic recording medium. The magnetic recording medium has a substrate, and a seedlayer deposited over the substrate. The seedlayer comprised of nickel (Ni), an alloying element (Y), and a metal oxide. An underlayer deposited over the seedlayer, and a magnetic data-storing granular layer deposited over the underlayer. Preferably, the alloying element (Y) is added to nickel (Ni) at less than or equal to 10 atomic percent of its maximum solubility limit at or above room temperature. The alloying element (Y) is soluble in nickel (Ni) at room temperature or at elevated temperatures. Also, the alloying element has a mass susceptibility of less than or equal to

$$1.5 \times {10}^{- 7} \frac{{m}^{3}}{kg} .$$

### In addition, the alloying element has an atomic radius greater than 1.24 Å.

The alloying element (Y) is selected from aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb). The metal oxide can have at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide can have a reduction potential more negative than nickel (Ni). An advantage of the nickel (Ni) alloy (Ni-y) with metal oxide is that the resulting deposited film or sputter target has a granular alloy microstructure with oxygen rich grain boundaries to provide further grain size refinement.

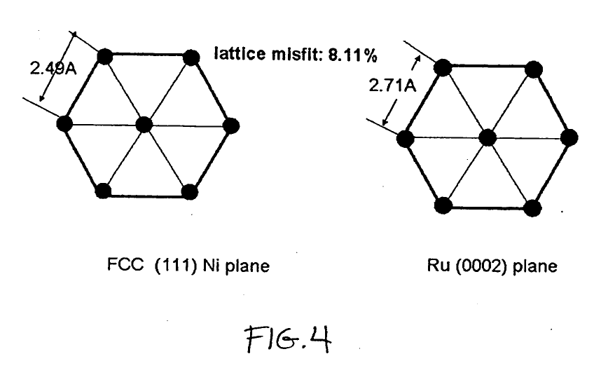

Due to the symmetry of the FCC (111) plane of nickel with the HCP (0002) plane of ruthenium (Ru), the present invention provides for the reduction of lattice mis-fit of crystalline underlayers, such as ruthenium (Ru) or ruthenium (Ru)-based underlayers or underlayers composed of different base metals, and nickel (Ni) alloy based seedlayers by alloying the crystalline seedlayer with nickel (Ni) and elements (Y) which are soluble in nickel (Ni) at room temperature or at elevated temperatures. The strong (0002) orientation in the ruthenium (Ru) or ruthenium (Ru) alloy based underlayer also promotes strong (0002) texture growth in the granular magnetic recording layer. As illustrated by way of example in FIG. 4, pure nickel (Ni) and ruthenium (Ru) films with their respective crystallographic orientations show a lattice misfit of 8.11%. These alloying elements (Y) form solid solutions with nickel (Ni) at room temperature or at elevated temperatures, and thus accordingly modify the in-plane lattice parameter of nickel (Ni), thereby reducing the lattice mis-fit. The alloying element (Y) in the nickel-based alloy (Ni—Y) with metal oxide has some solid solubility in nickel (Ni) at room temperature or at elevated temperatures, so that the alloying element (Y) forms a substitutional solid solution with nickel (Ni) and affects its in-plane, a-lattice parameter. Additionally, the alloying element is non-magnetic or weakly-magnetic in nature, with a mass susceptibility of less than or equal to

$$1.5 \times {10}^{- 7} \frac{{m}^{3}}{kg} .$$

Since the in-plane lattice parameter for nickel (Ni) is higher than that of ruthenium (Ru), the alloying element has an atomic radius greater than that of 1.24 Å, which is the atomic radius of nickel (Ni). Based on the above criteria, Table 2 (below) provides a list of alloying elements which can be alloyed with nickel (Ni) to form alloys (Ni—Y), which are further alloyed with metal oxide, and which provide for potential lattice matching with the subsequently deposited underlayer, further enhancing crystallinity.

TABLE 2
Alloying Elements that Reduce Lattice Misfit

| | | | | Mass | (RT) |
|---|---|---|---|---|---|
| Ele- | Atomic | Atomic | | Susceptibility | Solubility in |
| ment | Number | Radius | Structure | (10⁻⁸ m³/kg) | Nickel (Ni) |
| Al | 13 | 1.43 Å | Face- | 0.82 | 1385 C. |
| | | | Centered | | (21.2%); |
| | | | Cubic | | 400 C. (7%) |
| Si | 14 | 1.32 Å | Diamond | −0.16 | 1143 C. |
| | | | Cubic | | (15.8%); |
| | | | | | 700 C. (10%) |
| Ti | 22 | 1.47 Å | Hexagonal | 4.21 | 1304 C. |
| | | | Close-Pack | | (13.9%); |
| | | | | | 800 C. (7%) |
| V | 23 | 1.36 Å | Body- | 6.28 | 1202 C. (43%); |
| | | | Centered | | 200 C. (8%) |
| | | | Cubic | | |
| Zn | 30 | 1.37 Å | Hexagonal | −0.20 | 1040 C. |
| | | | Close-Pack | | (48.3%); RT |
| | | | | | (20%) |
| Ge | 32 | 1.37 Å | Diamond | | 1124 C. (12%); |
| | | | Cubic | | 200 C. (9.5%) |
| Nb | 41 | 1.47 Å | Body- | 2.81 | 1282 C. (14%); |
| | | | Centered | | 400 C. (3%) |
| | | | Cubic | | |
| Mo | 42 | 1.40 Å | Body- | 1.17 | 1317 C. (28%); |
| | | | Centered | | 700 C. (17.5%) |
| | | | Cubic | | |
| Ru | 44 | 1.34 Å | Hexagonal | 0.54 | 1550 C. |
| | | | Close-Pack | | (34.5%); |
| | | | | | 600 C. (4%) |
| Ta | 73 | 1.47 Å | Body- | 1.07 | 1330 C. (14%); |
| | | | Centered | | 800 C. (3%) |
| | | | Cubic | | |
| W | 74 | 1.41 Å | Body- | 0.39 | 1495 C. (17%); |
| | | | Centered | | RT (12%) |
| | | | Cubic | | |
| Re | 75 | 1.41 Å | Hexagonal | 0.46 | 1620 C. |
| | | | Close-Pack | | (17.4%); |
| | | | | | 600 C. (12%) |
| Os | 76 | 1.38 Å | Hexagonal | 0.06 | 1464 C. |
| | | | Close-Pack | | (11.7%); |
| | | | | | 600 C. (6%) |
| Tl | 81 | 1.71 Å | Hexagonal | −0.30 | 1387 C. |
| | | | Close-Pack | | (2.5%); 200 C. |
| | | | | | (2%) |
| Pb | 82 | 1.73 Å | Face- | −0.15 | 1340 C. |
| | | | Centered | | (11.5%); |
| | | | Cubic | | 200 C./RT |
| | | | | | (1.5%) |

The preferred elements to alloy with nickel (Ni) to form a nickel-based alloy (Ni—Y) would be aluminum (Al), titanium (Ti), vanadium (V), germanium (Ge), niobium (Nb), molybdenum (Mo), tantalum (Ta), tungsten (W), or rhenium (Re), as these elements have an atomic radius greater than 1.35 Å and a solubility of greater than or equal to three atomic percent. Other desirable elements to be used in forming the nickel-based (Ni—Y) alloy include silicon (Si) or ruthenium (Ru), as these element have an atomic radius of 1.30-1.35 Å, and a solubility of three atomic percent. Nickel can also be alloyed with zinc (Zn), osmium (Os), thallium (Tl) or lead (Pb) to reduce lattice mis-fit.

The alloying element (Y) in the nickel alloy (Ni—Y) based seedlayer with metal oxide can be added within the solubility range or in excess of the element's highest solubility limit for room temperature or above, in nickel (Ni). If added significantly in excess (as high as 10 atomic percent) of its maximum solubility limit in nickel (Ni), the alloy element (Y) can act both as an additive to reduce lattice mismatch and as a grain size reformer.

Nickel (Ni), the alloying element (Y), and metal oxide can used in a sputter target such as sputter target 300 of FIG. 3. The alloying element (Y) is present in the sputter target in an amount exceeding a solid solubility limit of the alloying element in face-centered cubic (FCC) phase nickel (Ni) at or above room temperature. The alloying element (Y) of the sputter target has a mass susceptibility of less than or equal to

$$1.5 \times {10}^{- 7} \frac{{m}^{3}}{kg} .$$

### In addition , the alloying element (Y) is present in the sputter target in an amount no more than 10 atomic percent than the solid solubility limit of the alloying element in face-centered cubic (FCC) phase nickel (Ni) at or above room temperature.

### Ni—X—Y

In various embodiments of the present invention, a ternary nickel (Ni) based alloy Ni—X—Y) composition may be formed, where a first alloying element (X) refines grain size because of its insolubility (or limited solid solubility at less than 10 atomic percent) in nickel (Ni) and added above its maximum solubility limit. A second alloying element (Y) can be added within the solubility range or in excess of the second alloying element's (Y) high solubility limit for room temperature or above, in nickel (Ni). Additionally, the alloying elements (X or Y) are non-magnetic or weakly magnetic in nature, with a mass susceptibility of less than or equal to

$$1.5 \times {10}^{- 7} \frac{{m}^{3}}{kg} .$$

Based on the above-identified citeria, Table 3 (below) provides a list of alloying elements which can be alloyed with nickel (Ni) to form ternary alloys (Ni—X—Y), where the first alloying element (X) provides for grain size reduction in the seedlayer film and the second alloying element (Y) provides enhanced lattice matching with the subsequently deposited underlayer, further enhancing crystallinity.

TABLE 3
Alloying Elements for Grain Size Refinement and Lattice Matching

| Grain Size Refiner | Elements for Lattice Matching |
|---|---|
| (Higher than its Highest | (Up to its Highest Solubility |
| Solubility at Room | Limit at Room |
| Temperature and Higher) | Temperature and Higher) |
| B | Al |
| C | Si |
| Mn | Ti |
| Cu | V |
| Y | Cr |
| Zr | Zn |
| Rh | Ge |
| Ag | Nb |
| Cd | Mo |
| Yb | Ru |
| Hf | Ta |
| Ir | W |
| Pt | Re |
| Au | Os |
| Bi | Tl |
| Th | Pb |

According to at least one embodiment of the present invention, a magnetic recording medium has a substrate, with a seedlayer deposited over the substrate. The seedlayer is comprised of nickel (Ni) and a first alloying element (X) and a second alloying element (Y). An underlayer is deposited over the seedlayer, with a magnetic data-storing granular layer deposited over the underlayer. The solubility of the first alloying element (X) in a face-centered cubic nickel (Ni) phase does not exceed 50 atomic percent at room temperature or at elevated temperatures. The second alloying element (Y) is added to nickel (Ni) at less than or equal to 10 atomic percent of its maximum solubility limit at or above room temperature, and has an atomic radius greater than 1.24 Å. Moreover, the first alloying element and the second alloying element have a mass susceptibility of less than or equal to

$$1.5 \times {10}^{- 7} \frac{{m}^{3}}{kg} .$$

### Accordingly, a ternary nickel alloy (Ni—X—Y) can be formed comprising both grain size reforming elements (X) and soluble elements (Y) for reducing lattice mismatch and eliminating interface stresses.

The first alloying element is selected from boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th). The second alloying element is selected from aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

Nickel (Ni) and the alloying elements (X and Y) can used in a sputter target such as sputter target 300 of FIG. 3. The alloying element (X) present in the sputter target is in an amount exceeding a solid solubility limit of the alloying element in face-centered cubic (FCC) phase nickel (Ni) at or above room temperature. In addition, the alloying element (X) can be present in the sputter target in an amount no more than 50 atomic percent greater than the solid solubility limit of the alloying element in face-centered cubic (FCC) phase nickel (Ni) at or above room temperature. Moreover, the alloying element (X) has a mass susceptibility of less than or equal to

$$1.5 \times {10}^{- 7} \frac{{m}^{3}}{kg} .$$

The alloying element (Y) is present in the sputter target in an amount exceeding a solid solubility limit of the alloying element in face-centered cubic (FCC) phase nickel (Ni) at or above room temperature. The alloying element (Y) of the sputter target has a mass susceptibility of less than or equal to

$$1.5 \times {10}^{- 7} \frac{{m}^{3}}{kg} .$$

In addition, the alloying element (Y) is present in the sputter target in an amount less than or equal to 10 atomic percent greater than the solid solubility limit of the alloying element in face-centered cubic (FCC) phase nickel (Ni) at or above room temperature.

The above-described ternary (Ni—X—Y) alloys for magnetic recording medium or sputter targets can be further alloyed with metal oxides in various embodiments of the invetion, thus forming seedlayer thin films with a granular microstructure containing metallic grains, surrounded by an oxygen rich grain boundary. The metal oxide can have at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide can have a reduction potential more negative than nickel (Ni), which is −0.257 V.

### Manufacturing a Recording Medium

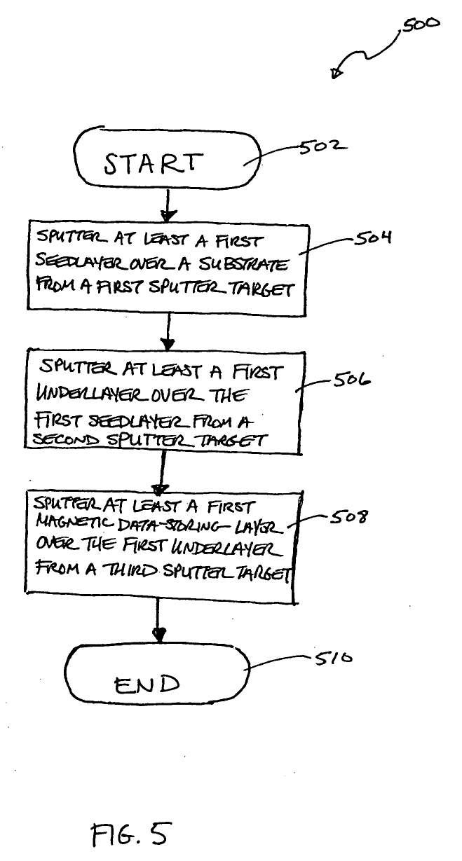

FIG. 5 illustrates a flowchart depicting method 500 for manufacturing a magnetic recording medium, according to a second embodiment of the present invention. Briefly, the method of manufacturing a magnetic recording medium includes the step of sputtering at least a first seedlayer over a substrate from a first sputter target, where the first sputter target is comprised of nickel (Ni) and an alloying element. The method also includes the steps of sputtering at least a first underlayer over the first seedlayer from a second sputter target, and sputtering at least a first magnetic data-storing granular layer over the first underlayer from a third sputter target.

In more detail, the process begins (step 502), at least a first seedlayer is sputtered over a substrate from a first sputter target, where the first sputter target is comprised of nickel (Ni) and an alloying element (step 504). In various embodiments of the present invention, the sputter target may further be comprised of metal oxides. By sputtering the first seedlayer “over” the substrate, it is not necessary that the first seedlayer be in direct physical communication with the seedlayer, since additional layers (e.g., anti-ferromagnetic layers, etc.) May be deposited between the substrate and the first seedlayer. Additionally, in various embodiments of the present invention, layers may be sputtered from the first sputter target or additional targets to form layers between the substrate and the first seedlayer.

According to one aspect associated with this arrangement, the solubility of the alloying element (X) in a face-centered cubic nickel (Ni) phase does not exceed 50 atomic percent at or above room temperature, and the alloying element has a mass susceptibility of less than or equal to

$$1.5 \times {10}^{- 7} \frac{{m}^{3}}{kg} .$$

Elements which meet these parameters and which could be used as the alloying element include, but are not limited to boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th). In at least one exemplary embodiment, the alloying element (X) is further alloyed with a metal oxide. The metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide has a reduction potential more negative than nickel (Ni).

According to a second, alternate aspect associated with this arrangement, the alloying element (Y) is soluble in a face-centered cubic nickel (Ni) phase does not exceed 10 atomic percent at or above room temperature, has a mass susceptibility of less than or equal to

$$1.5 \times {10}^{- 7} \frac{{m}^{3}}{kg} ,$$

and has an atomic radius greater than 1.24 Å. Elements which meet these parameters and which could be used as the alloying element include, but are not limited to aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Ti), or lead (Pb). In at least one exemplary embodiment, the alloying element (Y) is further alloyed with a metal oxide. The metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide has a reduction potential more negative than nickel (Ni).

According to a third, alternate aspect also associated with this arrangement, a first alloying element (X) and second alloying element (Y). The solubility of the alloying element (X) in a face-centered cubic nickel (Ni) phase does not exceed 50 atomic percent at or above room temperature, and the alloying element has a mass susceptibility of less than or equal to

$$1.5 \times {10}^{- 7} \frac{{m}^{3}}{kg} .$$

Elements which meet these parameters and which could be used as the alloying element include, but are not limited to boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th). The alloying element (Y) is soluble in a face-centered cubic nickel (Ni) phase does not exceed 10 atomic percent at or above room temperature, has a mass susceptibility of less than or equal to

$$1.5 \times {10}^{- 7} \frac{{m}^{3}}{kg} ,$$

and has an atomic radius greater than 1.24 Å. Elements which meet these parameters and which could be used as the alloying element include, but are not limited to aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), or lead (Pb). In at least one exemplary embodiment, the first alloying element (X) and second alloying element (Y) are further alloyed with a metal oxide. The metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof. The at least one metal element of the metal oxide has a reduction potential more negative than nickel (Ni).

At least a first underlayer is sputtered over the first seedlayer from a second sputter target (step 506). The first underlayer is comprised of ruthenium (Ru) or a ruthenium (Ru)-based alloy, or any other suitable element or alloy. In various embodiments of the present invention, the first underlayer may be co-sputtered with the seedlayer, although seedlayer could also be sputtered separately.

At least a first magnetic data-storing granular layer is sputtered over the first underlayer from a third sputter target (step 508). The first magnetic data-storing granular layer may be co-sputtered with the seedlayer or the first underlayer, although the seedlayer or the first underlayer could also be sputtered separately from the first magnetic data-storing granular layer as well. An additional layer or layers, such as a saturation magnetization adjustment layer may be sputtered over the first magnetic data-storing granular layer which may be CoPt, or CoPt further alloyed with chromium (Cr) or boron (B) or any suitable combination thereof. Other additional layers, such as a carbon (C) overcoat or a lubricant layer, may be sputtered over the first magnetic data-storing granular layer before the process ends (step 510).

The nickel-based alloys (with or without metal oxides) of the various exemplary embodiments described above can be made by powder metallurgical technique or by melt-casting techniques, with or without thermo-mechanical working. However, any other suitable production technique may be utilized.

Based on concepts disclosed by the various exemplary embodiments of the present invention, sputter targets of nickel (Ni) based alloys can be used to produce crystalline nickel (Ni) alloy based seedlayers with refined grain size, refining the grain size of the crystalline underlayer and promoting the subsequently epitaxially deposited granular magnetic layer. The various above-described embodiments of the present invention provide additional approaches to alloy the nickel (Ni) alloy based seedlayer, reducing the lattice mis-fit between the nickel (Ni) alloy based seedlayer and the underlayer, beneficially affecting the crystallinity of the underlayer. Each of these benefits enhances SNR and increases perpendicular anisotropy in the media stacks used for PMR.

The detailed description set forth below in connection with the appended drawings is intended as a description of various embodiments of the invention and is not intended to represent the only embodiments in which the invention may be practiced. The detailed description includes specific details for the purpose of providing a thorough understanding of the invention. However, it will be apparent to those skilled in the art that the invention may be practiced without these specific details. In some instances, well known structures and components are shown in block diagram form in order to avoid obscuring the concepts of the invention.

It is understood that the specific order or hierarchy of steps in the processes disclosed is an example of exemplary approaches. Based upon-design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

The previous description is provided to enable any person skilled in the art to practice the various embodiments described herein. Various modifications to these embodiments will be readily apparent to those skilled in the art, and the generic principles defined herein may be applied to other embodiments. Thus, the claims are not intended to be limited to the embodiments shown herein, but is to be accorded the full scope consistent with the language claims, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

1. A magnetic recording medium, comprising:
a substrate;
a seedlayer deposited over the substrate, the seedlayer comprised of nickel (Ni) and an alloying element, and wherein the seedlayer is further comprised of metal oxide;
an underlayer deposited over the seedlayer; and
a magnetic data-storing granular layer deposited over the underlayer,
wherein the solubility of the alloying element in a face-centered cubic nickel (Ni) phase does not exceed 50 atomic percent at or above room temperature, and
wherein the alloying element has a mass susceptibility of less than or equal to
$$1.5 \times {10}^{- 7} \frac{{m}^{3}}{\text{kg}} .$$

2. The magnetic recording medium according to claim 1, wherein the alloying element is selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th).

3. The magnetic recording medium according to claim 1, wherein the underlayer is comprised of ruthenium (Ru) or a ruthenium (Ru)-based alloy.

4. The magnetic recording medium according to claim 1, wherein the magnetic storing granular layer is CoCrPt.

5. The magnetic recording medium according to claim 4, wherein the CoCrPt magnetic storing granular layer further comprises oxygen (O).

6. The magnetic recording medium according to claim 1, further comprising a saturation magnetization adjustment layer deposited over the magnetic storing granular layer.

7. The magnetic recording medium according to claim 6, wherein the saturation magnetization adjustment layer is CoPt.

8. The magnetic recording medium according to claim 7, wherein the saturation magnetization adjustment layer is alloyed with chromium (Cr) or boron (B), or a combination thereof.

9. The magnetic recording medium according to claim 1, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

10. The magnetic recording medium according to claim 9, wherein the at least one metal element of the metal oxide has a reduction potential more negative than nickel (Ni).

11. A magnetic recording medium, comprising:
a substrate;
a seedlayer deposited over the substrate, the seedlayer comprised of nickel (Ni) and an alloying element, and wherein the seedlayer is further comprised of metal oxide;
an underlayer deposited over the seedlayer; and
a magnetic data-storing granular layer deposited over the underlayer,
wherein the alloying element is soluble in nickel (Ni) at or above room temperature,
wherein the alloying element has a mass susceptibility of less than or equal to
$$1.5 \times {10}^{- 7} \frac{{m}^{3}}{\text{kg}} ,$$
and
wherein the alloying element has an atomic radius greater than 1.24 Å.

12. The magnetic recording medium according to claim 11, wherein the alloying element is selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

13. The magnetic recording medium according to claim 11, wherein the alloying element is added to nickel (Ni) in an amount less than or equal to 10 atomic percent of its maximum solubility limit at or above room temperature.

14. The magnetic recording medium according to claim 11, wherein the underlayer is ruthenium (Ru) or a ruthenium (Ru)-based alloy.

15. The magnetic recording medium according to claim 11, wherein the magnetic storing granular layer is CoCrPt.

16. The magnetic recording medium according to claim 15, wherein the CoCrPt magnetic storing granular layer further comprises oxygen (O).

17. The magnetic recording medium according to claim 11, further comprising a saturation magnetization adjustment layer deposited over the magnetic storing granular layer.

18. The magnetic recording medium according to claim 17, wherein the saturation magnetization adjustment layer is CoPt.

19. The magnetic recording medium according to claim 18, wherein the saturation magnetization adjustment layer is alloyed with chromium (Cr) or boron (B), or a combination thereof.

20. The magnetic recording medium according to claim 11, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

21. The magnetic recording medium according to claim 20, wherein the at least one metal element of the metal oxide has a reduction potential more negative than nickel (Ni).

22. A magnetic recording medium, comprising:
a substrate;
a seedlayer deposited over the substrate, the seedlayer comprised of nickel (Ni) and a first alloying element and a second alloying element;
an underlayer deposited over the seedlayer; and
a magnetic data-storing granular layer deposited over the underlayer.

23. The magnetic recording medium according to claim 22, wherein solubility of the first alloying element in a face-centered cubic nickel (Ni) phase does not exceed 50 atomic percent at or above room temperature.

24. The magnetic recording medium according to claim 22, wherein the second alloying element is added to nickel (Ni) in an amount less than or equal to 10 atomic percent of its maximum solubility limit at or above room temperature.

25. The magnetic recording medium according to claim 22, wherein the first alloying element and the second alloying element have a mass susceptibility of less than or equal to
$$1.5 \times {10}^{- 7} \frac{{m}^{3}}{\text{kg}} .$$

26. The magnetic recording medium according to claim 22, wherein the second alloying element has an atomic radius greater than 1.24 Å.

27. The magnetic recording medium according to claim 22, wherein the first alloying element is selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th).

28. The magnetic recording medium according to claim 22, wherein the second alloying element is selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

29. The magnetic recording medium according to claim 22, wherein the underlayer is comprised of ruthenium (Ru) or a ruthenium (Ru)-based alloy.

30. The magnetic recording medium according to claim 22, wherein the magnetic storing granular layer is CoCrPt.

31. The magnetic recording medium according to claim 30, wherein the CoCrPt magnetic storing granular layer further comprises oxygen (O).

32. The magnetic recording medium according to claim 22, further comprising a saturation magnetization adjustment layer deposited over the magnetic storing granular layer.

33. The magnetic recording medium according to claim 32, wherein the saturation magnetization adjustment layer is CoPt.

34. The magnetic recording medium according to claim 33, wherein the saturation magnetization adjustment layer is alloyed with chromium (Cr) or boron (B), or a combination thereof.

35. The magnetic recording medium of claim 22, wherein the seedlayer further comprises a metal oxide.

36. The magnetic recording medium according to claim 35, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

37. The magnetic recording medium according to claim 36, wherein the at least one metal element of the metal oxide has a reduction potential more negative than nickel (Ni).

38. A sputter target, comprising:
nickel (Ni);
an alloying element selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th); and
metal oxide.

39. The sputter target of claim 38, wherein the alloying element is present in the sputter target in an amount no more than 50 atomic percent greater than the solid solubility limit of the alloying element in face-centered cubic (FCC) phase nickel (Ni) at or above room temperature.

40. The sputter target of claim 38, wherein the alloying element is for refining the grain size in an underlayer and a magnetic data-storing granular layer of a magnetic recording medium.

41. The sputter target of claim 38, wherein the alloying element has a mass susceptibility of less than or equal to
$$1.5 \times {10}^{- 7} \frac{{m}^{3}}{\text{kg}} .$$

42. The sputter target of claim 38, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

43. The sputter target of claim 42, wherein the at least one metal element of the metal oxide has a reduction potential more negative than nickel (Ni).

44. A sputter target, comprising:
nickel (Ni); and
an alloying element selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Ti), and lead (Pb); and
metal oxide.

45. The sputter target of claim 44, wherein the alloying element has a mass susceptibility of less than or equal to
$$1.5 \times {10}^{- 7} \frac{{m}^{3}}{\text{kg}} .$$

46. The sputter target of claim 44, wherein the alloying element is present in the sputter target in an amount less than or equal to 10 atomic percent of the solid solubility limit of the alloying element in face-centered cubic (FCC) phase nickel (Ni) at or above room temperature.

47. The sputter target of claim 44, wherein the alloying element is for reducing lattice misfit with an underlayer, reducing interface stresses, and enhancing the crystallinity of the underlayer for the magnetic data-storing granular layer of a magnetic recording medium.

48. The sputter target of claim 47, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

49. The sputter target of claim 48, wherein the at least one metal element of the metal oxide has a reduction potential more negative than nickel (Ni).

50. A sputter target, comprising:
nickel (Ni);
a first alloying element selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th); and
a second alloying element selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

51. The sputter target of claim 50, wherein the first alloying element is present in the sputter target in an amount no more than 50 atomic percent greater than the solid solubility limit of the alloying element in face-centered cubic (FCC) phase nickel (Ni) at or above room temperature.

52. The sputter target of claim 50, wherein the first alloying element is for refining the grain size in an underlayer and a magnetic data-storing granular layer of a magnetic recording medium.

53. The sputter target of claim 50, wherein the first alloying element and second alloying element have a mass susceptibility of less than or equal to
$$1.5 \times {10}^{- 7} \frac{{m}^{3}}{\text{kg}} .$$

54. The sputter target of claim 50, further comprising metal oxide.

55. The sputter target of claim 54, wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

56. The sputter target of claim 55, wherein the at least one metal element of the metal oxide has a reduction potential more negative than nickel (Ni).

57. The sputter target of claim 50, wherein the second alloying element has an atomic radius greater than 1.24 Å.

58. The sputter target of claim 50, wherein the second alloying element is present in the sputter target in an amount less than or equal to 10 atomic percent of the solid solubility limit of the alloying element in face-centered cubic (FCC) phase nickel (Ni) at or above room temperature.

59. The sputter target of claim 50, wherein the second alloying element is for reducing lattice misfit with an underlayer, reducing interface stresses, and enhancing the crystallinity of the underlayer for the magnetic data-storing granular layer of a magnetic recording medium.

60. A method of manufacturing a magnetic recording medium, comprising the steps of:
sputtering at least a first seedlayer over a substrate from a first sputter target, wherein the first sputter target is comprised of nickel (Ni) and an alloying element, wherein solubility of the alloying element in a face-centered cubic nickel (Ni) phase does not exceed 50 atomic percent at or above room temperature, wherein the alloying element has a mass susceptibility of less than or equal to
$$1.5 \times {10}^{- 7} \frac{{m}^{3}}{\text{kg}} ,$$
and wherein the first sputter target is further comprised of metal oxide;
sputtering at least a first underlayer over the first seedlayer from a second sputter target; and
sputtering at least a first magnetic data-storing granular layer over the first underlayer from a third sputter target.

61. The method according to claim 60, wherein the alloying element is selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th).

62. The method according to claim 60, wherein the metal oxide wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

63. The method according to claim 62, wherein the at least one metal element of the metal oxide can have a reduction potential more negative than nickel (Ni).

64. The method according to claim 60, wherein the first seedlayer, the first underlayer, or the first magnetic data-storing granular layer, or any combination thereof are sputtered using a co-sputtering assembly.

65. A method of manufacturing a magnetic recording medium, comprising the steps of:
sputtering at least a first seedlayer over a substrate from a first sputter target, wherein the first sputter target is comprised of nickel (Ni) and an alloying element, wherein solubility of the alloying element in a face-centered cubic nickel (Ni) phase is less than or equal to 10 atomic percent at or above room temperature, and wherein the alloying element has a mass susceptibility of less than or equal to
$$1.5 \times {10}^{- 7} \frac{{m}^{3}}{\text{kg}} ,$$
and wherein the first sputter target is further comprised of metal oxide;
sputtering at least a first underlayer over the first seedlayer from a second sputter target; and
sputtering at least a first magnetic data-storing granular layer over the first underlayer from a third sputter target.

66. The method according to claim 65, wherein the alloying element is selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

67. The method according to claim 65, wherein the alloying element has an atomic radius greater than 1.24 Å.

68. The method according to claim 65, wherein the metal oxide wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

69. The method according to claim 68, wherein the at least one metal element of the metal oxide can have a reduction potential more negative than nickel (Ni).

70. A method of manufacturing a magnetic recording medium, comprising the steps of:
sputtering at least a first seedlayer over a substrate from a first sputter target, wherein the first sputter target is comprised of nickel (Ni) and a first alloying element and a second alloying element, wherein solubility of the first alloying element in a face-centered cubic nickel (Ni) phase does not exceed 50 atomic percent at room temperature, wherein the solubility of the second alloying element in a face-centered cubic nickel (Ni) phase is less than or equal to 10 atomic percent at or above room temperature, and wherein the first and second alloying elements have a mass susceptibility of less than or equal to
$$1.5 \times {10}^{- 7} \frac{{m}^{3}}{\text{kg}} ;$$
sputtering at least a first underlayer over the first seedlayer from a second sputter target; and
sputtering at least a first magnetic data-storing granular layer over the first underlayer from a third sputter target.

71. The method according to claim 70, wherein the first alloying element is selected from the group consisting of boron (B), carbon (C), manganese (Mn), copper (Cu), yttrium (Y), zirconium (Zr), rhodium (Rh), silver (Ag), cadmium (Cd), ytterbium (Yb), hafnium (Hf), iridium (Ir), platinum (Pt), gold (Au), bismuth (Bi), and thorium (Th).

72. The method according to claim 70, wherein the second alloying element is selected from the group consisting of aluminum (Al), silicon (Si), titanium (Ti), vanadium (V), chromium (Cr), zinc (Zn), germanium (Ge), niobium (Nb), molybdenum (Mo), ruthenium (Ru), tantalum (Ta), tungsten (W), rhenium (Re), osmium (Os), thallium (Tl), and lead (Pb).

73. The method according to claim 70, wherein the second alloying element has an atomic radius greater than 1.24 Å.

74. The method according to claim 70, wherein the first sputter target is further comprised of a metal oxide.

75. The method according to claim 74, wherein the metal oxide wherein the metal oxide has at least one metal element that is silicon (Si), aluminum (Al), titanium (Ti), niobium (Nb), tantalum (Ta), zirconium (Zr), hafnium (Hf), tungsten (W), or any lanthanide, or any combination thereof.

76. The method according to claim 75, wherein the at least one metal element of the metal oxide can have a reduction potential more negative than nickel (Ni).
